(19) United States
(12) Patent Application Publication
(10) Pub. No.: US 2026/0072115 A1
(43) Pub. Date: Mar. 12, 2026

(54) METHOD FOR OPTIMIZING FLIP ANGLES IN MAGNETIC RESONANCE IMAGING VARIABLE FLIP ANGLE PULSE SEQUENCE, CEST IMAGING METHOD, MEDIUM, AND DEVICE

(71) Applicant: ZHEJIANG UNIVERSITY, Zhejiang (CN)

(72) Inventors: Yi ZHANG, Zhejiang (CN); Xingwang YONG, Zhejiang (CN)

(73) Assignee: ZHEJIANG UNIVERSITY, Zhejiang (CN)

(21) Appl. No.: 19/389,090

(22) Filed: Nov. 14, 2025

Related U.S. Application Data
(63) Continuation of application No. PCT/CN2024/090877, filed on Apr. 30, 2024.

(30) Foreign Application Priority Data
May 15, 2023 (CN) 202310544259.1

(51) Int. Cl. G01R 33/561; G01R 33/48; G01R 33/56; G01R 33/58

(52) U.S. Cl. CPC G01R 33/5615; G01R 33/4818; G01R 33/5607; G01R 33/586

(57) ABSTRACT

A method for optimizing flip angles in a magnetic resonance variable flip angle pulse sequence, a CEST imaging method, a medium, and a device are presented. A signal-to-noise ratio (SNR) enhancement problem is modeled as a flip angle optimization problem, and a total objective function composed of an SNR maximization objective term and a resolution penalty term is constructed, wherein the total objective function may be solved for an optimal solution by finding derivatives with respect to flip angles, so as to obtain an optimal flip angle capable of maximizing SNR. The objective function includes the resolution penalty term, so that resolution may also be considered in variable flip angle CEST when the SNR is optimized. Compared with a conventional filtering method, the present disclosure avoids noise amplification caused by filtering, and does not require manual presetting of a window function.

### CROSS-REFERENCE TO RELATED APPLICATION

This application is a continuation of International Application of PCT application serial No. PCT/CN2024/090877, filed on Apr. 30, 2024, which claims priority to Chinese Patent Application No. 202310544259.1, filed on May 15, 2023. The disclosures of the afore-mentioned applications are hereby incorporated by reference in their entireties.

### TECHNICAL FIELD

The present disclosure belongs to magnetic resonance imaging technology, and specifically relates to a method for optimizing flip angles in a magnetic resonance imaging variable flip angle pulse sequence, a CEST imaging method, a medium, and a device.

### DESCRIPTION OF RELATED ART

Chemical Exchange Saturation Transfer (CEST) imaging is a magnetic resonance molecular imaging technique capable of detecting various metabolites within the human body, including glucose, labile proteins, and polypeptides. The signal-to-noise ratio (SNR) of CEST imaging is crucial for the quality of the imaging. Given that CEST imaging relies on the attenuation of water signals, CEST imaging inherently possesses a low signal-to-noise ratio. In typical CEST imaging applications, such as in brain tumors, the contrast between normal tissue and lesions is only 2% to 3%, making CEST imaging vulnerable to SNR loss.

Furthermore, for CEST imaging to have a clinical value, both the imaging speed and spatial coverage thereof need to be close to those of existing structural imaging techniques. Gradient echo-based sequences, such as gradient echo (GRE) and echo planar imaging (EPI), although fast in imaging speed, are susceptible to magnetic susceptibility effects and prone to generating artifacts at tissue-air interfaces. Researchers have proposed a whole-brain CEST imaging sequence SPACE-CEST with variable flip angles (Sampling perfection with application optimized contrasts by using different flip angle evolutions, SPACE). This sequence is based on turbo spin echo (TSE) and is not affected by magnetic susceptibility. The SPACE-CEST sequence has an extended echo train length (ETL) by reducing the flip angles (FA), thereby shortening acquisition time while covering the whole brain. However, the constant flip angle 120° (CFA 120°) readout mode adopted in the SPACE-CEST sequence uses unoptimized flip angles with low SNR efficiency. Additionally, the higher flip angles adopted result in high specific absorption rate (SAR).

In the related art, researchers have studied combining variable flip angles with k-space filtering to enhance SNR. This method has a preset target window, which defines the signal-to-noise ratio (SNR) as a function of flip angles and the target window, and changes flip angles through iterative optimization to maximize the SNR. However, such a method involves filtering k-space signals. For low signals later in the echo train, filtering is multiplied by a large coefficient, which amplifies noise while enhancing the signal. In addition, the selection of the target window will also affect SNR.

### SUMMARY

The objective of the present disclosure lies in solving the problem of suboptimal SNR which results from unoptimized flip angles adopted by the variable flip angle CEST in existing whole-brain CEST imaging methods, and providing a method for optimizing flip angles in a magnetic resonance imaging variable flip angle pulse sequence, a CEST imaging method, a medium and a device.

The specific technical solution adopted by the present disclosure is as follows:

In a first aspect, the present disclosure provides a method for optimizing flip angles in a magnetic resonance imaging (MRI) variable flip angle pulse sequence, the method includes:
S1, the optimization of refocusing flip angles in an MRI variable flip angle pulse sequence can be written as the following objective function:

$${min}_{FAs} [ - a {\sum }_{i = 1}^{N - 1} {( {s}_{i} {w}_{i} )}^{2} + b \frac{{\sum }_{i = 1}^{N - 1} {\sum }_{j = 1}^{N - 1} {( {s}_{i} - {s}_{j} )}^{2}}{{\sum }_{i = 1}^{N - 1} {s}_{i}^{2}} ] , \\ s . t . 0 \leq FA \leq 180 ° .$$

In the formula: N−1 is the echo train length, sᵢ is a signal amplitude after an i-th refocus pulse is applied when there is no encoding gradient (which is only caused by flip angles and relaxation); wᵢ is a signal attenuation coefficient related to the i-th refocus pulse (attenuation is caused by factors such as dephasing, phase encoding, etc.); FAs=[α₁, α₂, . . . , α_{N-1}] is a flip angle set to be optimized, FA represents a flip angle αᵢ of the i-th refocus pulse, whose optimization range constraint is [0°, 180°]; a and b are two weight coefficients in the objective function, and both a and b are greater than 0;
S2, after rewriting the objective function using the extended phase graph (EPG) method, iterative solving is performed to obtain an optimal solution of an optimized flip angle set, which serves as a flip angle set value for the N−1 refocus pulses in the MRI variable flip angle pulse sequence, the optimized MRI variable flip angle pulse sequence is sent to a magnetic resonance scanner, which is configured to perform magnetic resonance CEST imaging to obtain CEST images.

As a preference of the above first aspect, each round of iteration process for solving the objective function is as follows:
S21, the three parts

$${\sum }_{i = 1}^{N - 1} {( {s}_{i} {w}_{i} )}^{2} , {\sum }_{i = 1}^{N - 1} {\sum }_{j = 1}^{N - 1} {( {s}_{i} - {s}_{j} )}^{2} , and {\sum }_{i = 1}^{N - 1} {s}_{i}^{2}$$

in the objective function are separately represented by the extended phase graph, where:

$${\sum }_{i = 1}^{N - 1} {\sum }_{j = 1}^{N - 1} {( {s}_{i} - {s}_{j} )}^{2}$$

is written as g using EPG:

$$g = 0.5 * {\sum }_{i = 2}^{N} {( {f}_{i} - {f}_{2} )}^{H} C ( {f}_{i} - {f}_{2} ) + {( {f}_{i} - {f}_{3} )}^{H} C ( {f}_{i} - {f}_{3} ) + … + {( {f}_{i} - {f}_{N} )}^{H} C ( {f}_{i} - {f}_{N} ) .$$

$${\sum }_{i = 1}^{N - 1} {s}_{i}^{2}$$

is written as n using EPG:

$$h = 0.5 * {\sum }_{i = 2}^{N} {f}_{i}^{H} {Cf}_{i} .$$

$${\sum }_{i = 1}^{N - 1} {( {s}_{i} {w}_{i} )}^{2}$$

is written as m using EPG:

$$m = 0.5 * {\sum }_{i = 2}^{N} {fi}_{H}^{} {D}_{i} {f}_{i} ,$$

Wherein C is a matrix for extracting a signal from an EPG state fᵢ. In the matrix C, only an element in the second row and second column of the matrix is 1 and all other elements are 0. Dᵢ is a matrix for extracting a signal from the EPG state fᵢ, wherein only an element in the second row and second column of the matrix is wᵢ² and all other elements are 0 in the matrix;
S22, derivatives of each part represented by the extended phase graph (EPG) is calculated with respect to N−1 flip angles using an adjoint state method. For n=1, 2, . . . , N−1, general formulas of derivatives of three parts are as follows:

The derivative of g with respect to the n-th flip angle αₙ is:

$$\frac{\partial g}{\partial {α}_{n}} = {λ}_{n} \frac{\partial {P}_{n}}{\partial {α}_{n}} {f}_{n} ,$$

wherein: when n=N−1,

$${λ}_{n} = 2 {\sum }_{i = 2}^{N} {( {f}_{n + 1} - {f}_{i} )}^{H} C ,$$

when n<N−1,

$${λ}_{n} = {P}_{n + 1} {λ}_{n + 1} + 2 {\sum }_{i = 2}^{N} {( {f}_{n + 1} - {f}_{i} )}^{H} C ;$$

The derivative of h with respect to the n-th flip angle αₙ is:

$$\frac{\partial h}{\partial {α}_{n}} = {μ}_{n} \frac{\partial {P}_{n}}{\partial {α}_{n}} {f}_{n} ,$$

wherein: when n=N−1, μₙ=fₙ₊₁^{H}C, when n<N−1, μₙ=μₙ₊₁Pₙ₊₁+fₙ₊₁^{H}C;

The derivative of m with respect to the n-th flip angle αₙ is:

$$\frac{\partial m}{\partial {α}_{n}} = {v}_{n} \frac{\partial {P}_{n}}{\partial {α}_{n}} {f}_{n} ,$$

wherein: when n=N−1, vₙ=fₙ₊₁^{H}Dₙ₊₁, when n<N−1, vₙ=vₙ₊₁Pₙ₊₁+fₙ₊₁^{H}Dₙ₊₁;

Among the derivatives of g, h, and m, Pₙ represents the state transfer operator, indicating the state transfer from an EPG state fₙ to another EPG state fₙ₊₁, for which the calculation formula is as follows:

$${P}_{n} = R ( {α}_{n} , {ϕ}_{n} ) E ( τ , {T}_{1} , {T}_{2} ) S ,$$

wherein S represents an effect of dephasing on the EPG state transfer; R(αₙ, Pₙ) represents an effect of refocus pulse on the EPG state transfer, for which the calculation formula is as follows:

$$R ( {α}_{n} , {ϕ}_{n} ) = ( \begin{matrix}{cos}^{2} ( {α}_{n} / 2 ) & exp ( 2 i {ϕ}_{n} ) {sin}^{2} ( {α}_{n} / 2 ) & - exp ( i {ϕ}_{n} ) sin ( {α}_{n} ) \\ exp ( 2 i {ϕ}_{n} ) {sin}^{2} ( {α}_{n} / 2 ) & {cos}^{2} ( {α}_{n} / 2 ) & exp ( - i {ϕ}_{n} ) sin ( {α}_{n} ) \\ - i / 2 exp ( - i {ϕ}_{n} ) sin ( {α}_{n} ) & i / 2 exp ( i {ϕ}_{n} ) sin ( {α}_{n} ) & cos {α}_{n}\end{matrix} ) ,$$

wherein: i is an imaginary unit; φₙ is a phase for the n-th refocus pulse;
E represents an effect of relaxation on the EPG state transfer, and the calculation formula thereof is as follows:

$$E = ( \begin{matrix}exp ( - τ / {T}_{2} ) & 0 & 0 \\ 0 & exp ( - τ / {T}_{2} ) & 0 \\ 0 & 0 & exo ( - τ / {T}_{1} )\end{matrix} ) .$$

In the formula, T₁ is a longitudinal relaxation time, T₂ is a transverse relaxation time, and τ is an echo spacing;
S23, according to an algebraic relationship of three parts in the objective function, derivatives of the three parts with respect to the flip angles are recombined to form combined derivatives of the objective function with respect to the N−1 flip angles, and optimization is performed based on the combined derivatives with respect to the flip angle set FAs=[α₁, α₂, . . . , α_{N-1}] to be optimized.

As a preference of the above first aspect, in the S23, when performing optimization on the flip angle set to be optimized based on the combined derivatives, a gradient descent algorithm or a conjugate gradient descent algorithm is adopted.

As a preference of the above first aspect, the signal attenuation coefficient wᵢ of the i-th refocus pulse is determined through a calibration experiment, and the determination method thereof is: a k-space signal [K₁, K₂, . . . , Kᵢ, . . . , K_{N-1}] collected from a water sample is pre-measured through experiments when a refocus pulse train with a set of applied flip angles among FAS=[α₁, α₂, . . . , αᵢ, . . . , α_{N-1}] is administered, and the longitudinal relaxation time T₁ and the transverse relaxation time T₂ of the water sample are measured; based on the longitudinal relaxation time T₁, the transverse relaxation time T₂, the flip angle FAs=[α₁, α₂, . . . , αᵢ, . . . , α_{N-1}], and echo spacing t, the signal amplitude [s₁, s₂, . . . , sᵢ, . . . , s_{N-1}] without attenuation is obtained through EPG simulation, and a ratio of Kᵢ to sᵢ is used as the signal attenuation coefficient wᵢ of the i-th refocus pulse.

As a preference of the above first aspect, the ratio of weight coefficients a/b is 100˜2000.

In a second aspect, the present disclosure provides a magnetic resonance CEST imaging method. The imaging sequence used in the method includes a CEST saturation module, a fat suppression module, and a variable flip angle readout module. The echo train length of the variable flip angle pulse sequence in the variable flip angle readout module is N−1, and the flip angles of the N−1 refocus pulses are obtained according to the method for optimizing flip angles in the MRI variable flip angle pulse sequence described in any one of claims 1 to 5.

In a third aspect, the present disclosure provides a computer-readable storage medium. A computer program is stored in the storage medium. When the computer program is executed by a processor, the method for optimizing flip angles in the MRI variable flip angle pulse sequence according to any solution in the first aspect is implemented.

In a fourth aspect, the present disclosure provides a computer electronic device, which includes a memory and a processor;

The memory is configured to store a computer program;

The processor is configured to implement the method for optimizing flip angles in the MRI variable flip angle pulse sequence according to any solution in the first aspect when executing the computer program.

In a fifth aspect, the present disclosure provides a magnetic resonance imaging device for a variable flip angle, which includes a magnetic resonance scanner and a control unit. A computer program is stored in the control unit. When the computer program is executed, the computer program implements the method for optimizing flip angles in the MRI variable flip angle pulse sequence according to any one of the solutions of the first aspect described above. The magnetic resonance scanner is utilized to perform magnetic resonance CEST imaging according to the optimized flip angle pulse sequence to obtain CEST images.

The present disclosure has the following advantageous effects compared to the related art:

The present disclosure models the SNR enhancement problem as a flip angle optimization problem for variable flip angle pulse sequences. This optimization problem has analytical derivatives for flip angles, making the problem efficiently solvable. Meanwhile, this optimization problem includes a resolution penalty term, which enables the control of blurring while optimizing SNR. Compared with the conventional filtering methods, the present disclosure avoids noise amplification caused by filtering, and does not require manual selection of a window function.

### BRIEF DESCRIPTION OF THE DRAWINGS

FIG. 1 is a timing diagram of SNR-boosted variable flip angle CEST imaging sequence, with an echo train length ETL of N−1, wherein the readout that has N−1 variable flip angles is the part that requires optimization;

FIG. 2 is a schematic diagram of an EPG state;

FIG. 3A to FIG. 3I show optimized flip angles, signal curves, and point spread functions obtained under different settings. In the figures of 3A to 3C, only SNR is considered. In the figures of 3D to 3F, only resolution is considered. In the figures of 3G to 3I, both SNR and resolution are considered.

FIG. 4A to FIG. 4C show a partial magnification of a slice of the image acquired with flip angles optimized in the case of considering only resolution. A partial magnification of a slice of the image acquired using CFA 120° is shown, and quantitative blurriness of different slice images is shown.

### DESCRIPTION OF THE EMBODIMENTS

The present disclosure will be further elaborated and described below in combination with the accompanying drawings and specific embodiments. The technical features of various embodiments in the present disclosure may be combined accordingly provided that they do not conflict with each other.

To make the above objectives, features and advantages of the present disclosure more obvious and understandable, the specific implementation methods of the present disclosure are described in detail below in combination with the accompanying drawings. Many specific details are set forth in the following description in order to fully understand the present disclosure. However, the present disclosure may be implemented in many other ways different from those described herein, and those skilled in the art may make similar improvements without departing from the essence of the present disclosure. Therefore, the present disclosure is not limited by the specific embodiments disclosed below. The technical features in various embodiments of the present disclosure may be correspondingly combined without conflicting with each other.

The inventive concept of the present disclosure is to model the signal-to-noise ratio (SNR) enhancement problem as a flip angle optimization problem, construct a combined objective function composed of a SNR maximization objective term and a resolution penalty term, where the resolution penalty term adopts a form of two terms divided. The combined objective function can be minimized by taking derivatives with respect to flip angles to solve the optimal solution, thereby obtaining the flip angles that may maximize SNR.

For ease of understanding, before elaborating on the specific technical solutions of the present disclosure, the principles of the present disclosure are first specifically elaborated.

### 1. SNR Enhancement Modeled as Optimization Problem

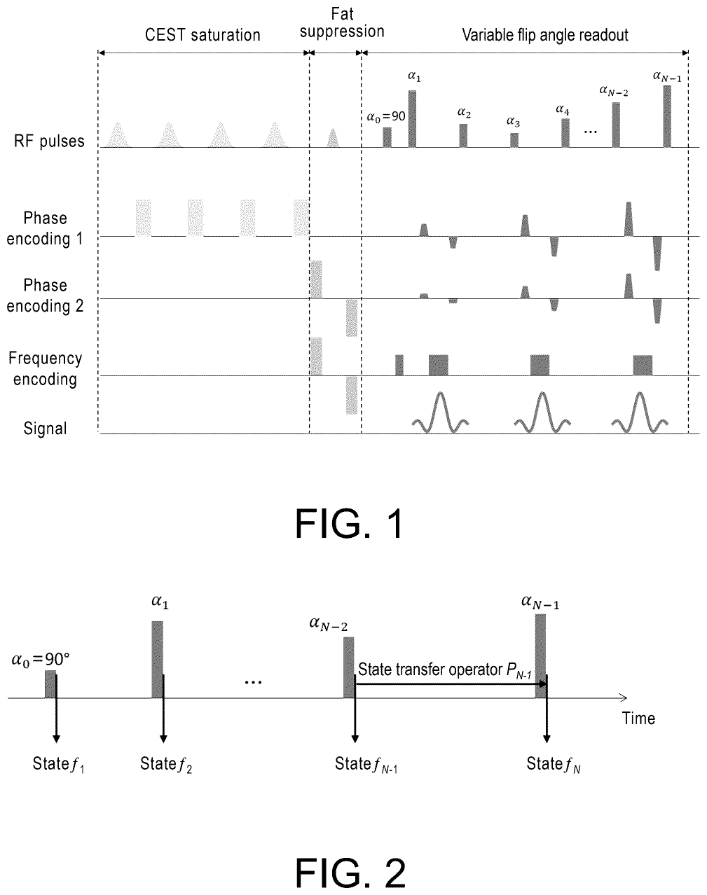

The present disclosure provides an SNR-enhanced variable flip angle CEST imaging method, referred to as SNR-boosted variable flip angle CEST. This method models SNR as a function of flip angle, optimizes this function to maximize SNR, and simultaneously constrains the signal to reduce image blurring caused by signal modulation. An SNR-boosted variable flip angle CEST sequence timing diagram is shown in FIG. 1, which includes three parts: CEST saturation, fat suppression, and signal readout. The present disclosure optimizes the signal readout part.

For a uniform object, an i-th echo thereof in a k-space may be represented as

$${K}_{i} = {s}_{i} * {w}_{i} . \qquad ( 1 )$$

In the formula, sᵢ is a signal amplitude related to flip angles and relaxation, wᵢ is a signal attenuation caused by factors such as gradients, magnetic field inhomogeneity, signal scaling, etc. In TSE imaging, when using a series of refocus pulses with flip angles all at 180°, sᵢ=exp (−i*TE/T₂). When using other flip angles, sᵢ is a function of T₁, T₂, and flip angles, and the value thereof may be obtained through Bloch simulation or Extended Phase Graph (EPG) simulation. When acquiring the k-space center and the magnetic field is homogeneous, and without considering global signal scaling, wᵢ has a value of 1. Typically, due to dephasing, wᵢ is less than 1. The attenuation coefficient wᵢ may be calculated through the following formula.

$${w}_{i} = \frac{{K}_{i}}{{s}_{i}} , \qquad ( 2 )$$

wherein Kᵢ is an experimentally measured k-space signal, and sᵢ is a signal amplitude obtained through EPG simulation.

According to Parseval's theorem, an energy in an image space and the k-space are equal, that is

$${Σ}_{i} {I}_{i}^{2} = {Σ}_{i} {K}_{i}^{2} \qquad ( 3 )$$

wherein Iᵢ is a signal value in the image space. Assuming the variance of noise is constant, to improve the signal-to-noise ratio in the image space, the signal value in the image space needs to increase, which means the signal value in the k-space increases. Therefore, the signal-to-noise ratio maximization problem may be represented as follows:

$${max}_{FAs} {\sum }_{i = 1}^{N - 1} {( {s}_{i} {w}_{i} )}^{2} \\ s . t . 0 \leq FA \leq 180 ° \qquad ( 4 )$$

wherein N−1 is the number of echoes in each echo train, that is, the echo train length ETL. Since wᵢ of the center of the k-space is greater than wᵢ of the edge of the k-space, the optimization result of the above problem will cause the signal at the center of the k-space to be too large while the signal at the edge is too low, resulting in image blurring. Therefore, it is necessary to introduce a penalty term for resolution.

$${min}_{FAs} [ - a {\sum }_{i = 1}^{N - 1} {( {s}_{i} {w}_{i} )}^{2} + b \frac{{\sum }_{i = 1}^{N - 1} {\sum }_{j = 1}^{N - 1} {( {s}_{i} - {s}_{j} )}^{2}}{{\sum }_{i = 1}^{N - 1} {s}_{i}^{2}} ] \\ s . t . 0 \leq FA \leq 180 ° \qquad ( 5 )$$

The coefficients a and b control the weights of SNR and resolution, and the ratio of weight coefficients a/b is preferably 100˜2000. This resolution penalty term ensures that signals are close to each other while making the signal values themselves as large as possible. When only the resolution term is optimized, a constant signal may be obtained, which is equivalent to an ideal point spread function (PSF).

### 2. Solving the Optimization Problem

The following focuses on solving the above optimization problem using EPG.

### 2.1. Introduction of EPG Framework

For a variable flip angle pulse sequence with ETL of N−1, assuming that the flip angle of the excitation pulse thereof be α₀=90°, the flip angles of the N−1 refocus pulses are respectively [α₁, . . . , α_{N-1}], the EPG states are [f₁, f₂, . . . , f_{N-1}, f_{N}], and each EPG state fᵢ is a column vector, wherein the second component represents a signal value sᵢ. As shown in FIG. 2, f₁ is the state immediately after the α₀=90° excitation pulse is applied, f₂ is the state immediately after the first refocus pulse α₁ is applied, fₙ is the state immediately after the (n−1)-th refocus pulse is applied, and so on. The transfer from the EPG state fₙ to fₙ₊₁ is described by the state transfer operator Pₙ.

$${f}_{n + 1} = {P}_{n} {f}_{n} \\ {P}_{n} = R ( ≢ {0}_{n} , {ϕ}_{n} ) E ( τ , {T}_{1} , {T}_{2} ) S \qquad ( 6 )$$

wherein R represents the effect of the refocus pulse on the EPG state transfer, φₙ is the phase of the n-th refocus pulse; E represents the effect of relaxation on the EPG state transfer; and S represents the effect of dephasing on the EPG state transfer.

The effect of the refocus pulse on the EPG state transfer is R, which is a function related to the flip angle α and the phase φ of the refocus pulse, with the expression as follows:

$$R ( {α}_{n} , {ϕ}_{n} ) = ( \begin{matrix}{cos}^{2} ( {α}_{n} / 2 ) & exp ( 2 i {ϕ}_{n} ) {sin}^{2} ( {α}_{n} / 2 ) & - exp ( i {ϕ}_{n} ) sin ( {α}_{n} ) \\ exp ( - 2 i {ϕ}_{n} ) {sin}^{2} ( {α}_{n} / 2 ) & {cos}^{2} ( {α}_{n} / 2 ) & exp ( - i {ϕ}_{n} ) sin ( {α}_{n} ) \\ - i / 2 exp ( - i {ϕ}_{n} ) sin ( {α}_{n} ) & i / 2 exp ( i {ϕ}_{n} ) sin ( {α}_{n} ) & cos {α}_{n}\end{matrix} ) \qquad ( 7 )$$

$$E = ( \begin{matrix}exp ( - τ / {T}_{2} ) & 0 & 0 \\ 0 & exp ( - τ / {T}_{2} ) & 0 \\ 0 & 0 & exp ( - τ / {T}_{1} )\end{matrix} ) \qquad ( 8 )$$

### 2.2. Optimization Problem Decomposition and Solving Derivatives of Subproblem

$${min}_{FAs} - a {\sum }_{i = 1}^{N - 1} {( {S}_{i} {W}_{i} )}^{2} + b \frac{{\sum }_{i = 1}^{N - 1} {\sum }_{j = 1}^{N - 1} {( {s}_{i} - {s}_{j} )}^{2}}{{\sum }_{i = 1}^{N - 1} {s}_{i}^{2}}$$

$$s . t . 0 \leq FA \leq {180}^{0}$$

The objective function in the optimization problem (5) is split into 3 parts:

$${\sum }_{i = 1}^{N - 1} {( {s}_{i} {w}_{i} )}^{2} ,$$

$${\sum }_{i = 1}^{N - 1} {\sum }_{j = 1}^{N - 1} {( {s}_{i} - {s}_{j} )}^{2} , and {\sum }_{i = 1}^{N - 1} {s}_{i}^{2} .$$

With respect to these three parts, the derivative with respect to the refocus pulse flip angle is calculated respectively.

$${\sum }_{i = 1}^{N - 1} {\sum }_{j = 1}^{N - 1} {( {s}_{i} - {s}_{j} )}^{2}$$

is considered first, which is represented by the EPG state as follows:

$$g = 0.5 * {\sum }_{i = 2}^{N} {\sum }_{j = 2}^{N} {( {f}_{i} - {f}_{j} )}^{H} C ( {f}_{i} - {f}_{j} ) = 0.5 * {\sum }_{i = 2}^{N} {( {f}_{i} - {f}_{2} )}^{H} C ( {f}_{i} - {f}_{2} ) + {( {f}_{i} - {f}_{3} )}^{H} C ( {f}_{i} - {f}_{3} ) + … + {( {f}_{i} - {f}_{N} )}^{H} C ( {f}_{i} - {f}_{N} ) \qquad ( 9 )$$

wherein C(2,2)=1, other elements of the matrix C are all 0. The matrix C is utilized for extracting signals from the EPG state, for example,

$${s}_{i}^{2} = {f}_{i}^{H} {Cf}_{i} .$$

The following considers the use of the adjoint state method (ASM) to determine the derivative of g with respect to the last flip angle α_{N-1}:

$$\frac{\partial g}{\partial {α}_{N - 1}} = 0.5 * \frac{\partial }{\partial {α}_{N - 1}} \{ \qquad ( 10 )$$

$${( {f}_{2} - {f}_{N} )}^{H} C ( {f}_{2} - {f}_{N} ) +$$

$${( {f}_{3} - {f}_{N} )}^{H} C ( {f}_{3} - {f}_{N} ) +$$

$$…$$

$${( {f}_{N - 1} - {f}_{N} )}^{H} C ( {f}_{N - 1} - {f}_{N} ) +$$

$${( {f}_{N} - {f}_{2} )}^{H} C ( {f}_{N} - {f}_{2} ) + {( {f}_{N} - {f}_{3} )}^{H} C ( {f}_{N} - {f}_{3} ) + … + {( {f}_{N} - {f}_{N} )}^{H} C ( {f}_{N} - {f}_{N} ) \}$$

$$= 0.5 * \frac{\partial }{\partial {α}_{N - 1}} 1 * [ {( {f}_{2} - {f}_{N} )}^{H} C ( {f}_{2} - {f}_{N} ) + {( {f}_{3} - {f}_{N} )}^{H} C ( {f}_{3} - {f}_{N} ) + … + {( {f}_{N} - {f}_{N} )}^{H} C ( {f}_{N} - {f}_{N} ) ]$$

$$= 2 * [ \text{} {( {f}_{2} - {f}_{N} )}^{H} C ( 0 - {f}_{N} ) + {( {f}_{3} - {f}_{N} )}^{H} C ( 0 - {f}_{N} ) + … + {( {f}_{N - 1} - {f}_{N} )}^{H} C ( {f}_{0} - {f}_{N} ) ]$$

$$= 2 * {\sum }_{i = 2}^{N} {( {f}_{N} - {f}_{i} )}^{H} C {f}_{N}$$

$$= 2 * {\sum }_{i = 2}^{N} {( {f}_{N} - {f}_{i} )}^{H} C \frac{\partial {P}_{N - 1} {f}_{N - 1}}{\partial {α}_{N - 1}}$$

$$= {λ}_{N - 1} \frac{\partial {P}_{N - 1}}{\partial {α}_{N - 1}} {f}_{N - 1}$$

wherein

$${λ}_{N - 1} = 2 {\sum }_{i = 2}^{N} {( {f}_{N} - {f}_{i} )}^{H} C .$$

The derivative of g with respect to the second-to-last flip angle α_{N-2} is further considered,

$$\frac{\partial g}{\partial {α}_{N - 2}} = 0.5 * \frac{\partial }{\partial {α}_{N - 1}} \{ \qquad ( 11 )$$

$${( {f}_{2} - {f}_{N - 1} )}^{H} C ( {f}_{2} - {f}_{N - 1} ) + {( {f}_{2} - {f}_{N} )}^{H} C ( {f}_{2} - {f}_{N} ) +$$

$${( {f}_{3} - {f}_{N - 1} )}^{H} C ( {f}_{3} - {f}_{N - 1} ) + {( {f}_{3} - {f}_{N} )}^{H} C ( {f}_{3} - {f}_{N} ) +$$

$$…$$

$$+ {( {f}_{N - 2} - {f}_{N - 1} )}^{H} C ( {f}_{N - 2} - {f}_{N - 1} ) + {( {f}_{N - 2} - {f}_{N} )}^{H} C ( {f}_{N - 2} - {f}_{N} ) +$$

$${( {f}_{N - 1} - {f}_{2} )}^{H} C ( {f}_{N - 1} - {f}_{2} ) + {( {f}_{N - 1} - {f}_{3} )}^{H} C ( {f}_{N - 1} - {f}_{3} ) + … + {( {f}_{N - 1} - {f}_{N} )}^{H} C ( {f}_{N - 1} - {f}_{N} ) +$$

$${( {f}_{N} - {f}_{2} )}^{H} C ( {f}_{N} - {f}_{2} ) + {( {f}_{N} - {f}_{3} )}^{H} C ( {f}_{N} - {f}_{3} ) + … + {( {f}_{N} - {f}_{N} )}^{H} C ( {f}_{N} - {f}_{N} ) \}$$

The right side of the formula (11) is split into 3 parts, which are respectively defined as

$$D = 0.5 * \{ \qquad ( 12 )$$

$${( {f}_{2} - {f}_{N - 1} )}^{H} C ( {f}_{2} - {f}_{N - 1} ) + {( {f}_{2} - {f}_{N} )}^{H} C ( {f}_{2} - {f}_{N} ) +$$

$${( {f}_{3} - {f}_{N - 1} )}^{H} C ( {f}_{3} - {f}_{N - 1} ) + {( {f}_{3} - {f}_{N} )}^{H} C ( {f}_{3} - {f}_{N} ) +$$

$$…$$

$$+ {( {f}_{N - 2} - {f}_{N - 1} )}^{H} C ( {f}_{N - 2} - {f}_{N - 1} ) + {( {f}_{N - 2} - {f}_{N} )}^{H} C ( {f}_{N - 2} - {f}_{N} ) \}$$

$$E = 0. 5 * \{ {( {f}_{N - 1} - {f}_{2} )}^{H} C ( {f}_{N - 1} - {f}_{2} ) + {( {f}_{N - 1} - {f}_{3} )}^{H} C ( {f}_{N - 1} - {f}_{3} ) + … + {( {f}_{N - 1} - {f}_{N} )}^{H} C ( {f}_{N - 1} - {f}_{N} ) \} \qquad ( 13 )$$

$$( 14 )$$

$$F = 0. 5 * \{ {( {f}_{N} - {f}_{2} )}^{H} C ( {f}_{N} - {f}_{2} ) + {( {f}_{N} - {f}_{3} )}^{H} C ( {f}_{N} - {f}_{3} ) + … + {( {f}_{N} - {f}_{N} )}^{H} C ( {f}_{N} - {f}_{N} ) \}$$

The derivatives of the three parts with respect to α_{N-2} are respectively as follows:

$$\frac{\partial D}{\partial {α}_{N - 2}} = {\sum }_{i = 2}^{N - 2} {( {f}_{N - 1} - {f}_{i} )}^{H} {Cf}_{N - 1}^{′} + {\sum }_{i = 2}^{N - 2} {( {f}_{N} - {f}_{i} )}^{H} {Cf}_{N}^{′} \qquad ( 15 )$$

$$\begin{matrix}\frac{\partial E}{\partial {α}_{N - 2}} = {( {f}_{N - 1} - {f}_{2} )}^{H} {Cf}_{N - 1}^{′} + {( {f}_{N - 1} - {f}_{3} )}^{H} {Cf}_{N - 1}^{′} + \\ … + {( {f}_{N - 1} - {f}_{N} )}^{H} C ( {f}_{N - 1}^{′} - {f}_{N}^{′} ) \\ = {\sum }_{i = 2}^{N} {( {f}_{N - 1} - {f}_{i} )}^{H} {Cf}_{N - 1}^{′} + {( {f}_{N} - {f}_{N - 1} )}^{H} {Cf}_{N}^{′}\end{matrix} \qquad ( 16 )$$

$$\begin{matrix}\frac{\partial F}{\partial {α}_{N - 2}} = {( {f}_{N} - {f}_{2} )}^{H} {Cf}_{N}^{′} + {( {f}_{N} - {f}_{3} )}^{H} {Cf}_{N}^{′} + \\ … + {( {f}_{N} - {f}_{N - 1} )}^{H} C ( {f}_{N}^{′} - {f}_{N - 1}^{′} ) \\ = {\sum }_{i = 2}^{N - 1} {( {f}_{N} - {f}_{i} )}^{H} {Cf}_{N}^{′} + {( {f}_{N - 1} - {f}_{N} )}^{H} {Cf}_{N - 1}^{′}\end{matrix} \qquad ( 17 )$$

By combining the formulas (15), (16) and (17), the following may be obtained:

$$\begin{matrix}\frac{\partial g}{\partial {α}_{N - 2}} = 2 {\sum }_{i = 2}^{N} {( {f}_{N} - {f}_{i} )}^{H} {Cf}_{N}^{′} + 2 {\sum }_{i = 2}^{N} {( {f}_{N - 1} - {f}_{i} )}^{H} {Cf}_{N - 1}^{′} \\ = \{ 2 {P}_{N - 1} {\sum }_{i = 2}^{N} {( {f}_{N} - {f}_{i} )}^{H} C + 2 {\sum }_{i = 2}^{N} {( {f}_{N - 1} - {f}_{i} )}^{H} C \} {f}_{N - 1}^{′} \\ = \{ {P}_{N - 1} {λ}_{N - 1} + 2 {\sum }_{i = 2}^{N} {( {f}_{N - 1} - {f}_{i} )}^{H} C \} {f}_{N - 1}^{′} \\ = {λ}_{N - 2} {f}_{N - 1}^{′} \\ = {λ}_{N - 2} \frac{\partial {P}_{N - 2}}{\partial {α}_{N - 2}} {f}_{N - 2}\end{matrix} \qquad ( 18 )$$

wherein

$${λ}_{N - 2} = {P}_{N - 1} {λ}_{N - 1} + 2 {\sum }_{i = 2}^{N} {( {f}_{N - 1} - {f}_{i} )}^{H} C .$$

Similarly, with respect to the flip angle αₙ of the n-th (n<N−1) refocus pulse, the general formula for the derivative of g with respect to αₙ may be as follows:

$$\frac{\partial g}{\partial {α}_{n}} = {λ}_{n} \frac{\partial {P}_{n}}{\partial {α}_{n}} {f}_{n} \qquad ( 19 )$$

wherein

$${λ}_{n} = {P}_{n + 1} {λ}_{n + 1} + 2 {\sum }_{i = 2}^{N} {( {f}_{n + 1} - {f}_{i} )}^{H} C .$$

At this point, the analytical derivatives of g with respect to all the flip angles to be optimized have been obtained.

Similarly, the derivatives of

$${\sum }_{i = 1}^{N - 1} {( {s}_{i} {w}_{i} )}^{2} and {\sum }_{i = 1}^{N - 1} {s}_{i}^{2}$$

with respect to the N−1 flip angles may be derived, specifically as follows:

With respect to

$${\sum }_{i = 1}^{N - 1} {s}_{i}^{2} ,$$

the derivative is represented by the EPG state as follows:

$$h = 0.5 * {\sum }_{i = 2}^{N} {f}_{i}^{H} {Cf}_{i} . \qquad ( 20 )$$

The derivative of h with respect to the last flip angle is considered first, and the derivative may be obtained by the adjoint state method as follows:

$$\frac{\partial h}{\partial {α}_{N - 1}} = {μ}_{N - 1} \frac{\partial {P}_{N - 1}}{\partial {α}_{N - 1}} {f}_{N - 1} \qquad ( 21 )$$

wherein:

$${μ}_{N - 1} = {f}_{N}^{H} C . \qquad ( 22 )$$

Similarly, with respect to the flip angle αₙ of the n-th (n<N−1) refocus pulse, the general formula for the derivative h with respect to αₙ may be as follows:

$$\frac{\partial h}{\partial {α}_{n}} = {μ}_{n} \frac{\partial {P}_{n}}{\partial {α}_{n}} {f}_{n} \qquad ( 23 )$$

wherein:

$${μ}_{n} = {μ}_{n + 1} {P}_{n + 1} + {f}_{n + 1}^{H} C . \qquad ( 24 )$$

With respect to

$${\sum }_{i = 1}^{N - 1} {( {s}_{i} {w}_{i} )}^{2} ,$$

the derivative is represented by the EPG state as follows:

$$m = 0.5 * {\sum }_{i = 2}^{N} {f}_{i}^{H} {D}_{i} {f}_{i} \qquad ( 25 )$$

wherein, Dᵢ(2,2)=wᵢ², other elements of matrix Dᵢ are all 0. The derivative of m with respect to the last flip angle is considered first as follows:

$$\frac{\partial m}{\partial {α}_{N - 1}} = {v}_{N - 1} \frac{\partial {P}_{N - 1}}{\partial {α}_{N - 1}} {f}_{N - 1} \qquad ( 26 )$$

wherein:

$${v}_{N - 1} = {f}_{N}^{H} {D}_{N} . \qquad ( 27 )$$

Similarly, with respect to the flip angle αₙ of the n-th (n<N−1) refocus pulse, the general formula for the derivative of m with respect to αₙ may be obtained as follows:

$$\frac{\partial m}{\partial {α}_{n}} = {v}_{n} \frac{\partial {P}_{n}}{\partial {α}_{n}} {f}_{n} \qquad ( 28 )$$

wherein:

$${v}_{n} = {v}_{n + 1} {P}_{n + 1} + {f}_{n + 1}^{H} {D}_{n + 1} . \qquad ( 29 )$$

Therefore, the problem (5) may be expressed in an analytical derivative form, and may be resolved using algorithms such as gradient descent, conjugate gradient descent, and others.

Based on the above theoretical discussion, the present disclosure demonstrates the specific implementation method and technical effects of the method for optimizing flip angles in the magnetic resonance variable flip angle pulse sequence through specific embodiments below.

### EMBODIMENTS

In the present embodiment, the specific steps of the method for optimizing flip angles in the magnetic resonance variable flip angle pulse sequence are as follows:
S1, a flip angle optimization problem of its N−1 refocus pulses is modeled as the following objective function with respect to a magnetic resonance flip angle pulse sequence with an echo train length of N−1:

$${min}_{FAs} - a {\sum }_{i = 1}^{N - 1} {( {s}_{i} {w}_{i} )}^{2} + b \frac{{\sum }_{i = 1}^{N - 1} {\sum }_{j = 1}^{N - 1} {( {s}_{i} - {s}_{j} )}^{2}}{{\sum }_{i = 1}^{N - 1} {s}_{i}^{2}} \\ s . t . 0 \leq FA \leq 180 °$$

In the formula: sᵢ is the signal amplitude after the i-th refocus pulse is applied, which is only caused by flip angles and relaxation when there is no encoding gradient; wᵢ is the signal attenuation coefficient related to the i-th refocus pulse, and the attenuation is caused by factors such as dephasing, phase encoding, etc.; FAs=[α₁, α₂, . . . , α_{N-1}] is the flip angle set to be optimized, and FA represents a flip angle αᵢ of any i-th refocus pulse, whose optimization range constraint is [0°, 180°]; a and b are two weight coefficients in the objective function, and both a and b are greater than 0.

In the present embodiment, the signal attenuation coefficient wᵢ of the i-th refocus pulse is determined through calibration experiment determination, and the determination method for which is as follows:

A k-space signal [K₁, K₂, . . . , Kᵢ, . . . , K_{N-1}] collected from a water sample is pre-measured through experiments when a refocus pulse with an applied flip angle among FAs=[α₁, α₂, . . . , αᵢ, . . . , α_{N-1}] is administered, and a longitudinal relaxation time T₁ and a transverse relaxation time T₂ of the water sample are measured; based on the longitudinal relaxation time T₁, the transverse relaxation time T₂, the flip angle FAS=[α₁, α₂, . . . , αᵢ, . . . , α_{N-1}], and echo spacing τ, a signal amplitude [s₁, s₂, . . . , sᵢ, . . . , s_{N-1}] without attenuation is obtained through EPG simulation, and a ratio of Kᵢ to sᵢ is used as the signal attenuation coefficient wᵢ of the i-th refocus pulse.

Wherein the flip angles FAs=[α₁, α₂, . . . , αᵢ, . . . , α_{N-1}] respectively applied by the N−1 refocus pulses during the experiment may be selected from a set of commonly used values according to relevant literature.
S2, after rewriting the objective function using an extended phase graph (EPG), iterative solving is performed to obtain an optimal solution of an optimized flip angle set, which serves as a flip angle set value for the N−1 refocus pulses in the magnetic resonance variable flip angle pulse sequence.

In the above process of solving the objective function, each iteration process is as follows:
S21, the three parts

$${\sum }_{i = 1}^{N - 1} {( {s}_{i} {w}_{i} )}^{2} , {\sum }_{i = 1}^{N - 1} {\sum }_{j = 1}^{N - 1} {( {s}_{i} - {s}_{j} )}^{2} , and {\sum }_{i = 1}^{N - 1} {s}_{i}^{2}$$

in the objective function are separately represented by the extended phase graph, where:

$${\sum }_{i = 1}^{N - 1} {\sum }_{j = 1}^{N - 1} {( {s}_{i} - {s}_{j} )}^{2}$$

is written as g using the extended phase graph:

$$g = 0.5 * {\sum }_{i = 2}^{N} {( {f}_{i} - {f}_{2} )}^{H} C ( {f}_{i} - {f}_{2} ) + {( {f}_{i} - {f}_{3} )}^{H} C ( {f}_{i} - {f}_{3} ) + … + {( {f}_{i} - {f}_{N} )}^{H} C ( {f}_{i} - {f}_{N} ) \qquad ( 30 )$$

$${\sum }_{i = 1}^{N - 1} {s}_{i}^{2}$$

is written as m by using the extended phase graph:

$$h = 0.5 * {\sum }_{i = 2}^{N} {f}_{i}^{H} {Cf}_{i}$$

$${\sum }_{i = 1}^{N - 1} {( {s}_{i} {w}_{i} )}^{2}$$

is written as m by using the extended phase graph:

$$m = 0.5 * {\sum }_{i = 2}^{N} {f}_{i}^{H} {D}_{i} {f}_{i}$$

wherein C is a matrix for extracting a signal from an EPG state fᵢ, wherein only an element in the second row and second column of the matrix is 1 and all other elements are 0 in the matrix. Dᵢ is a matrix for extracting a signal from the EPG state fᵢ and applying weights, wherein only an element in the second row and second column of the matrix is wᵢ² and all other elements are 0 in the matrix;
S22, derivatives of each part represented by the extended phase graph is calculated with respect to N−1 flip angles using an adjoint state method, wherein with respect to n=1, 2, . . . , N−1, general formulas of derivatives of three parts are as follows:

The derivative of g with respect to the n-th flip angle αₙ is:

$$\frac{\partial g}{\partial {α}_{n}} = {λ}_{n} \frac{\partial {P}_{n}}{\partial {α}_{n}} {f}_{n}$$

wherein: when n=N−1,

$${λ}_{n} = 2 {\sum }_{i = 2}^{N} {( {f}_{n + 1} - {f}_{i} )}^{H} C ;$$

when n<N−1,

$${λ}_{n} = {P}_{n + 1} {λ}_{n + 1} + 2 {\sum }_{i = 2}^{N} {( {f}_{n + 1} - {f}_{i} )}^{H} C ;$$

The derivative of h with respect to the n-th flip angle αₙ is:

$$\frac{\partial h}{\partial {α}_{n}} = {μ}_{n} \frac{\partial {P}_{n}}{\partial {α}_{n}} {f}_{n}$$

wherein: when n=N−1, μₙ=fₙ₊₁^{H}C; when n<N−1, μₙ=μₙ₊₁Pₙ₊₁+fₙ₊₁^{H}C;

The derivative of m with respect to the n-th flip angle αₙ is:

$$\frac{\partial m}{\partial {α}_{n}} = {v}_{n} \frac{\partial {P}_{n}}{\partial {α}_{n}} {f}_{n}$$

wherein: when n=N−1, vₙ=fₙ₊₁^{H}Dₙ₊₁; when n<N−1, vₙ=vₙ₊₁Pₙ₊₁+fₙ₊₁^{H}Dₙ₊₁;

Among the derivatives of g, h, and m, Pₙ represents a state transfer operator, indicating a state transfer from an EPG state fₙ to another EPG state fₙ₊₁, for which the calculation formula is as follows:

$${P}_{n} = R ( {α}_{n} , {ϕ}_{n} ) E ( τ , {T}_{1} , {T}_{2} ) S$$

wherein S represents an effect of dephasing on the EPG state transfer; R(αₙ, Pₙ) represents an effect of refocus pulse on the state transfer, for which the calculation formula is as follows:

$$R ( {α}_{n} , {ϕ}_{n} ) = ( \begin{matrix}{cos}^{2} ( {α}_{n} / 2 ) & exp ( 2 i {ϕ}_{n} ) {sin}^{2} ( {α}_{n} / 2 ) & - exp ( i {ϕ}_{n} ) sin ( {α}_{n} ) \\ exp ( - 2 i {ϕ}_{n} ) {sin}^{2} ( {α}_{n} / 2 ) & {cos}^{2} ( {α}_{n} / 2 ) & exp ( - i {ϕ}_{n} ) sin ( {α}_{n} ) \\ - i / 2 exp ( - i {ϕ}_{n} ) sin ( {α}_{n} ) & i / 2 exp ( i {ϕ}_{n} ) sin ( {α}_{n} ) & cos {α}_{n}\end{matrix} )$$

wherein: i is an imaginary unit; φₙ is a phase for the n-th refocus pulse;
E represents an effect of relaxation on the EPG state transfer, and the calculation formula thereof is as follows:

$$E = ( \begin{matrix}exp ( - τ / {T}_{2} ) & 0 & 0 \\ 0 & exp ( - τ / {T}_{2} ) & 0 \\ 0 & 0 & exp ( - τ / {T}_{1} )\end{matrix} )$$

In the formula, T₁ is the longitudinal relaxation time, T₂ is the transverse relaxation time, and τ is the echo spacing;
S23, according to an algebraic relationship of three parts in the objective function, derivatives of the three parts with respect to the flip angles are recombined to form combined derivatives of the objective function with respect to the N−1 flip angles, and optimization is performed based on the combined derivatives with respect to the flip angle set FAs=[α₁, α₂, . . . , α_{N-1}] to be optimized.

In the present embodiment, when performing optimization on the flip angle set to be optimized based on the combined derivatives, a gradient descent algorithm or a conjugate gradient descent algorithm may be adopted.

Based on the optimal solution of the flip angle set obtained from the above optimization process, the optimal solution may be used as the values of the flip angles of the N−1 refocus pulses in the variable flip angle pulse sequence of the imaging sequence, thereby forming an imaging sequence for magnetic resonance CEST imaging, which is utilized for magnetic resonance imaging (MRI). As illustrated in FIG. 1, the imaging sequence includes a CEST saturation module, a fat suppression module, and a variable flip angle readout module. In the variable flip angle readout module, the echo train length of the variable flip angle pulse sequence is N−1, and the flip angles of the N−1 refocus pulses are determined according to the aforementioned method for optimizing the flip angle in the magnetic resonance variable flip angle pulse sequence. The CEST saturation module and the fat suppression module in the sequence are part of the existing technology, and specific details of the present embodiment may be derived from FIG. 1, which will not be further elaborated.

To demonstrate the effect of the two optimization terms in the objective function in the present disclosure, this embodiment optimizes the flip angle for three cases: (1) optimizing only for SNR, i.e., set the coefficient a to 1 and set the coefficient b to 0; (2) optimizing only for resolution, i.e., set the coefficient a to 0 and set the coefficient b to 1; (3) optimizing for both SNR and resolution simultaneously, i.e., set the coefficient a to 1 and set the coefficient b to 0.001.

In this embodiment, during the optimization process, the physiological parameters are set as: T₁=1000 ms, T₂=100 ms; the sequence parameters are: echo spacing (tesp)=4.06 ms, echo train length ETL=140; the initial values and upper and lower limits of the flip angles to be optimized are: the initial values of all flip angles in the entire echo train are 10°, the upper limits of all flip angles are 180°, and the lower limits of all flip angles are 0°.

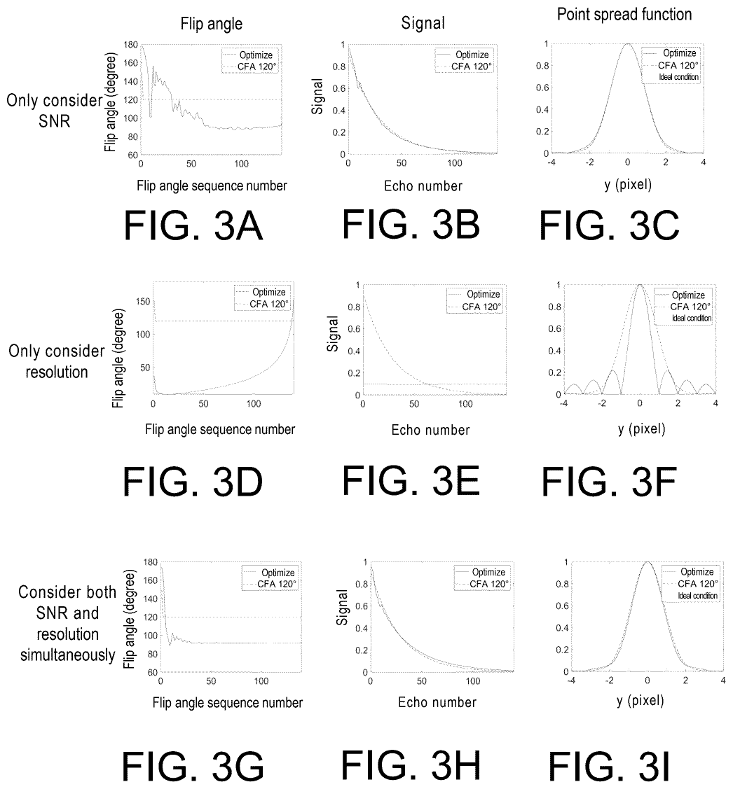

The results when optimizing only for SNR are shown in FIG. 3A, FIG. 3B, and FIG. 3C. The optimized signal curve is similar to CFA 120°, however, the flip angles adopted are much smaller. The results when optimizing only for resolution are shown in FIG. 3D, FIG. 3E, and FIG. 3F. The optimized signal curve remains constant throughout the entire echo train, correspondingly, the obtained point spread function coincides with the ideal point spread function. The results when optimizing for both SNR and resolution simultaneously are shown in FIG. 3G, FIG. 3H, and FIG. 3I. The optimized signal increases by 4.7% compared to the CFA 120° signal, while the full width half maximum (FWHM) of the obtained point spread function is 6.1% smaller than that of CFA 120°.

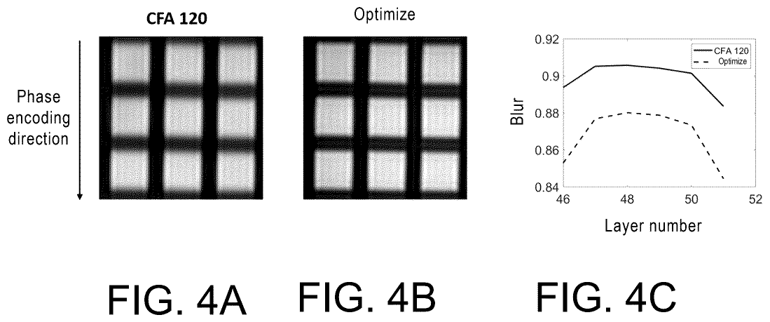

FIG. 4B shows an image using the flip angles obtained by optimizing resolution only, which has no obvious blur in the phase encoding direction compared to an image acquired using CFA 120° in FIG. 4A. The quantitative blur in FIG. 4C further indicates that CFA 120° has a higher degree of blur, and the image is more blurred.

It should be noted that the method for optimizing flip angles in the magnetic resonance variable flip angle pulse sequence provided in the above embodiment may essentially exist in the form of a program processing flow. Therefore, similarly, based on the same inventive concept, another preferred embodiment of the present disclosure also provides a computer electronic device corresponding to the method for optimizing flip angles in the magnetic resonance variable flip angle pulse sequence, which includes a memory and a processor;

The memory is configured to store a computer program;

The processor is configured to implement the method for optimizing flip angles in the magnetic resonance variable flip angle pulse sequence as described above when executing the computer program.

Similarly, based on the same inventive concept, another preferred embodiment of the present disclosure also provides a computer-readable storage medium corresponding to the method for optimizing flip angles in the magnetic resonance variable flip angle pulse sequence provided by the above embodiments. A computer program is stored in the storage medium. When the computer program is executed by a processor, the method for optimizing flip angles in the magnetic resonance variable flip angle pulse sequence as described above is implemented.

It may be understood that the forms of the above memory and storage medium may include Random Access Memory (RAM), and may also include Non-Volatile Memory (NVM), such as at least one disk memory. Meanwhile, the storage medium may also be various media that may store program codes such as a USB flash drive, a mobile hard disk, a magnetic disk or an optical disk. Of course, with the widespread application of cloud servers, the above software program may also be carried on cloud platforms to provide corresponding services, therefore the computer-readable storage medium is not limited to the form of local hardware.

It may be understood that the above-mentioned processor may be a general-purpose processor, including a Central Processing Unit (CPU), a Network Processor (NP), etc.; the processor may also be a Digital Signal Processor (DSP), an Application Specific Integrated Circuit (ASIC), a Field-Programmable Gate Array (FPGA) or other programmable logic devices, a discrete gate or transistor logic devices, discrete hardware components.

Additionally, it should be noted that those skilled in the art can clearly understand that, for convenience and brevity of description, the specific operation process of the device described above may refer to the corresponding process in the aforementioned method embodiments, which will not be repeated here. In the various embodiments provided in the present application, the division of steps or modules in the device and method is merely a logical function division, and there may be other division methods in actual implementation, for example, multiple modules or steps may be combined or integrated together, and one module or step may also be split.

Furthermore, the logic instructions in the aforementioned memory may be implemented in the form of software function units and when sold or used as independent products, may be stored in a computer-readable storage medium. Based on such understanding, the technical solution of the present disclosure essentially or the part that contributes to the related art or the part of the technical solution may be embodied in the form of a software product. The computer software product is stored in a storage medium, including several instructions for causing a computer device (which may be a personal computer, server, or network device, etc.) to execute all or part of the steps of the method described in various embodiments of the present disclosure.

Similarly, based on the same inventive concept, another preferred embodiment of the present disclosure also provides a magnetic resonance imaging device of a variable flip angle corresponding to the method for optimizing flip angles in the magnetic resonance variable flip angle pulse sequence provided by the above embodiments, which includes a magnetic resonance scanner and a control unit. Wherein:
The control unit stores a computer program. When the computer program is executed, the computer program implements the method for optimizing flip angles in the magnetic resonance variable flip angle pulse sequence according to any one of the solutions of the first aspect described above;
The magnetic resonance scanner is configured to perform magnetic resonance CEST imaging according to the optimized flip angle pulse sequence and obtaining CEST images.

It should be noted that the magnetic resonance scanner may be any magnetic resonance scanner capable of implementing CEST imaging, and has a structure belonging to the related art and may adopt mature commercial products without limitation on specific models. In addition, the control unit of the magnetic resonance imaging device should have imaging sequences necessary for implementing CEST imaging and other software programs in addition to storing the above computer program.

Of course, the above control unit may be an independent control unit, or may be a control unit that comes with the magnetic resonance scanner, that is, the above method for optimizing flip angles in the magnetic resonance variable flip angle pulse sequence may be integrated into the control unit of the magnetic resonance imaging device in the form of a data processing program, so that the magnetic resonance scanner may directly optimize the variable flip angle pulse sequence in the imaging sequence online and perform magnetic resonance CEST imaging according to the optimized flip angle pulse sequence without requiring additional new control units.

The above-described embodiments are only preferred solutions of the present disclosure, but they are not used to limit the present disclosure. Those skilled in the relevant technical field may also make various changes and modifications without departing from the spirit and scope of the present disclosure. Therefore, all technical solutions obtained by adopting equivalent substitution or equivalent transformation fall within the scope to be protected by the present disclosure.

What is claimed is:

1. A method for optimizing flip angles in a magnetic resonance variable flip angle pulse sequence, comprising:
S1, a flip angle optimization problem of its N−1 refocus pulses is modeled as the following objective function with respect to flip angles:
$${min}_{F A s} [ - a {\sum }_{i = 1}^{N - 1} {( {s}_{i} {w}_{i} )}^{2} + b \frac{{\sum }_{i = 1}^{N - 1} {\sum }_{j = 1}^{N - 1} {( {s}_{i} - {s}_{j} )}^{2}}{{\sum }_{i = 1}^{N - 1} {s}_{i}^{2}} ] \\ s . t . 0 \leq FA \leq 180 °$$
in the formula: sᵢ is a signal amplitude after an i-th refocus pulse is applied when there is no encoding gradient; wᵢ is a signal attenuation coefficient related to the i-th refocus pulse; FAS=[α₁, α₂, . . . , α_{N-1}] is a flip angle set to be optimized, FA represents a flip angle αᵢ of the i-th refocus pulse, whose optimization range constraint is [0°, 180°]; a and b are two weight coefficients in the objective function, and both a and b are greater than 0;
S2, after rewriting the objective function using an extended phase graph (EPG) method, iterative solving is performed to obtain an optimal solution of an optimized flip angle set, which serves as a flip angle set value for the N−1 refocus pulses in the magnetic resonance variable flip angle pulse sequence, and the optimized magnetic resonance variable flip angle pulse sequence is sent to a magnetic resonance scanner, which is configured to perform magnetic resonance CEST imaging to obtain CEST images.

2. The method for optimizing the flip angles in the magnetic resonance variable flip angle pulse sequence according to claim 1, wherein each round of iteration process for solving the objective function is as follows:
S21, three parts
$${\sum }_{i = 1}^{N - 1} {( {s}_{i} {w}_{i} )}^{2} , {\sum }_{i = 1}^{N - 1} {\sum }_{j = 1}^{N - 1} {( {s}_{i} - {s}_{j} )}^{2} {\sum }_{i = 1}^{{N}_{- 1}} {s}_{i}^{2}$$
in the objective function are separately represented by the extended phase graph, where:
$${\sum }_{i = 1}^{N - 1} {\sum }_{j = 1}^{N - 1} {( {s}_{i} - {s}_{j} )}^{2}$$
is written as g using the extended phase graph:
$$g = 0.5 * {\sum }_{i = 2}^{N} {( {f}_{i} - {f}_{2} )}^{H} C ( {f}_{i} - {f}_{2} ) + {( {f}_{i} - {f}_{3} )}^{H} C ( {f}_{i} - {f}_{3} ) + … + {( {f}_{i} - {f}_{N} )}^{H} C ( {f}_{i} - {f}_{N} )$$
$${\sum }_{i = 1}^{N - 1} {s}_{i}^{2}$$
is written as h using the extended phase graph:
$$h = 0.5 * {\sum }_{i = 2}^{N} {f}_{i}^{H} C {f}_{i}$$
$${\sum }_{i = 1}^{N - 1} {( {s}_{i} {w}_{i} )}^{2}$$
is written as m by using the extended phase graph:
$$m = 0.5 * {\sum }_{i = 2}^{N} {f}_{i}^{H} {D}_{i} {f}_{i}$$
wherein C is a matrix for extracting a signal from an EPG state fᵢ, wherein only an element in a second row and second column of the matrix is 1 and all other elements are 0 in the matrix, and Dᵢ is a matrix for extracting a signal from the EPG state fᵢ, wherein only the element in the second row and second column of the matrix is wᵢ² and all other elements are 0 in the matrix;
S22, derivatives of each part represented by the extended phase graph is calculated with respect to N−1 flip angles using an adjoint state method, wherein with respect to n=1, 2, . . . , N−1, general formulas of derivatives of the three parts are as follows:
a derivative of g with respect to an n-th flip angle αₙ is:
$$\frac{\partial g}{\partial {α}_{n}} = {λ}_{n} \frac{\partial {P}_{n}}{\partial {α}_{n}} {f}_{n}$$
wherein: when n=N−1,
$${λ}_{n} = 2 {\sum }_{i = 2}^{N} {( {f}_{n + 1} - {f}_{i} )}^{H} C ,$$
when n<N−1,
$${λ}_{n} = {P}_{n + 1} {λ}_{n + 1} + 2 {\sum }_{i = 2}^{N} {( {f}_{n + 1} - {f}_{i} )}^{H} C ;$$
a derivative of h with respect to the n-th flip angle αₙ is:
$$\frac{\partial h}{\partial {α}_{n}} = {μ}_{n} \frac{\partial {P}_{n}}{\partial {α}_{n}} {f}_{n}$$
wherein: when n=N−1, μₙ=fₙ₊₁^{H}C, when n<N−1, μₙ=μₙ₊₁Pₙ₊₁+fₙ₊₁^{H}C;
a derivative of m with respect to the n-th flip angle αₙ is:
$$\frac{\partial m}{\partial {α}_{n}} = {v}_{n} \frac{\partial {P}_{n}}{\partial {α}_{n}} {f}_{n}$$
wherein: when n=N−1, vₙ=fₙ₊₁^{H}Dₙ₊₁, when n<N−1, vₙ=vⁿ⁺¹Pₙ₊₁+fₙ₊₁^{H}Dₙ₊₁;
among the derivatives of g, h, and m, Pₙ represents a state transfer operator indicating a state transfer from an extended phase graph state fₙ to another extended phase graph state fₙ₊₁, for which a calculation formula is as follows:
$${P}_{n} = R ( {α}_{n} , {ϕ}_{n} ) E ( τ , {T}_{1} , {T}_{2} ) S$$
wherein S represents an effect of dephasing on the extended phase graph state transfer; R(αₙ, φₙ) represents an effect of the refocus pulse on the state transfer, for which a calculation formula is as follows:
$$R ( {α}_{n} , {ϕ}_{n} ) = ( \begin{matrix}{cos}^{2} ( {α}_{n} / 2 ) & exp ( 2 i {ϕ}_{n} ) {sin}^{2} ( {α}_{n} / 2 ) & - exp ( i {ϕ}_{n} ) sin ( {α}_{n} ) \\ exp ( - 2 i {ϕ}_{n} ) {sin}^{2} ( {α}_{n} / 2 ) & {cos}^{2} ( {α}_{n} / 2 ) & exp ( - i {ϕ}_{n} ) sin ( {α}_{n} ) \\ - i / 2 exp ( - i {ϕ}_{n} ) sin ( {α}_{n} ) & i / 2 exp ( i {ϕ}_{n} ) sin ( {α}_{n} ) & cos {α}_{n}\end{matrix} )$$
in the formula: i is an imaginary unit; φₙ is a phase for an n-th refocus pulse;
E represents an effect of relaxation on the extended phase graph state transfer, and a calculation formula thereof is as follows:
$$E = ( \begin{matrix}exp ( - τ / {T}_{2} ) & 0 & 0 \\ 0 & exp ( - τ / {T}_{2} ) & 0 \\ 0 & 0 & exp ( - τ / {T}_{1} )\end{matrix} )$$
in the formula, T₁ is a longitudinal relaxation time, T₂ is a transverse relaxation time, and t is an echo spacing;
S23, according to an algebraic relationship of the three parts in the objective function, the derivatives of the three parts with respect to the flip angles are recombined to form combined derivatives of the objective function with respect to the N−1 flip angles, and optimization is performed based on the combined derivatives with respect to the flip angle set FAs=[α₁, α₂, . . . , α_{N-1}] to be optimized.

3. The method for optimizing the flip angles in the magnetic resonance variable flip angle pulse sequence according to claim 1, wherein in the S23, when performing optimization on the flip angle set to be optimized based on the combined derivatives, a gradient descent algorithm or a conjugate gradient descent algorithm is adopted.

4. The method for optimizing the flip angles in the magnetic resonance variable flip angle pulse sequence according to claim 1, wherein the signal attenuation coefficient wᵢ of the i-th refocus pulse is determined through a calibration experiment, and the determination method thereof is:
a k-space signal [K₁, K₂, . . . , Kᵢ, . . . , K_{N-1}] collected from a water sample is pre-measured through experiments when a refocus pulse with an applied flip angle among FAS=[α₁, α₂, . . . , α_{N-1}] is administered, and the longitudinal relaxation time T₁ and the transverse relaxation time T₂ of the water sample are measured; based on the longitudinal relaxation time T₁, the transverse relaxation time T₂, the flip angle FAs=[α₁, α₂, . . . , α_{N-1}], and an echo spacing t, a signal amplitude [s₁, s₂, . . . , sᵢ, . . . , s_{N-1}] without attenuation is obtained through EPG simulation, and a ratio of Kᵢ to sᵢ is used as the signal attenuation coefficient wᵢ of the i-th refocus pulse.

5. The method for optimizing the flip angles in the magnetic resonance variable flip angle pulse sequence according to claim 1, wherein a ratio of weight coefficients a/b is 100˜2000.

6. A magnetic resonance Chemical exchange saturation transfer (CEST) imaging method, wherein an imaging sequence used in the method comprises a CEST saturation module, a fat suppression module, and a variable flip angle readout module, wherein the echo train length of the variable flip angle pulse sequence in the variable flip angle readout module is N−1, and the flip angles of the N−1 refocus pulses are obtained according to the method for optimizing the flip angles in the magnetic resonance variable flip angle pulse sequence according to claim 1.

7. A computer-readable storage medium, wherein a computer program is stored in the storage medium, and when the computer program is executed by a processor, the method for optimizing the flip angles in the magnetic resonance variable flip angle pulse sequence according to claim 1 is implemented.

8. A computer electronic device, comprising a memory and a processor;
the memory, configured to store a computer program;
the processor, configured to implement the method for optimizing the flip angles in the magnetic resonance variable flip angle pulse sequence according to claim 1 when executing the computer program.

9. A magnetic resonance imaging device for a variable flip angle, characterized in comprising a magnetic resonance scanner and a control unit, wherein a computer program is stored in the control unit, and when the computer program is executed, the computer program implements the method for optimizing the flip angles in the magnetic resonance variable flip angle pulse sequence according to claim 1; the magnetic resonance scanner is utilized to perform magnetic resonance Chemical exchange saturation transfer (CEST) imaging according to the optimized flip angle pulse sequence to obtain CEST images.

10. A magnetic resonance Chemical exchange saturation transfer (CEST) imaging method, wherein an imaging sequence used in the method comprises a CEST saturation module, a fat suppression module, and a variable flip angle readout module, wherein the echo train length of the variable flip angle pulse sequence in the variable flip angle readout module is N−1, and the flip angles of the N−1 refocus pulses are obtained according to the method for optimizing the flip angles in the magnetic resonance variable flip angle pulse sequence according to claim 2.

11. A magnetic resonance Chemical exchange saturation transfer (CEST) imaging method, wherein an imaging sequence used in the method comprises a CEST saturation module, a fat suppression module, and a variable flip angle readout module, wherein the echo train length of the variable flip angle pulse sequence in the variable flip angle readout module is N−1, and the flip angles of the N−1 refocus pulses are obtained according to the method for optimizing the flip angles in the magnetic resonance variable flip angle pulse sequence according to claim 3.

12. A magnetic resonance Chemical exchange saturation transfer (CEST) imaging method, wherein an imaging sequence used in the method comprises a CEST saturation module, a fat suppression module, and a variable flip angle readout module, wherein the echo train length of the variable flip angle pulse sequence in the variable flip angle readout module is N−1, and the flip angles of the N−1 refocus pulses are obtained according to the method for optimizing the flip angles in the magnetic resonance variable flip angle pulse sequence according to claim 4.

13. A magnetic resonance Chemical exchange saturation transfer (CEST) imaging method, wherein an imaging sequence used in the method comprises a CEST saturation module, a fat suppression module, and a variable flip angle readout module, wherein the echo train length of the variable flip angle pulse sequence in the variable flip angle readout module is N−1, and the flip angles of the N−1 refocus pulses are obtained according to the method for optimizing the flip angles in the magnetic resonance variable flip angle pulse sequence according to claim 5.

14. A computer-readable storage medium, wherein a computer program is stored in the storage medium, and when the computer program is executed by a processor, the method for optimizing the flip angles in the magnetic resonance variable flip angle pulse sequence according to claim 2 is implemented.

15. A computer-readable storage medium, wherein a computer program is stored in the storage medium, and when the computer program is executed by a processor, the method for optimizing the flip angles in the magnetic resonance variable flip angle pulse sequence according to claim 3 is implemented.

16. A computer-readable storage medium, wherein a computer program is stored in the storage medium, and when the computer program is executed by a processor, the method for optimizing the flip angles in the magnetic resonance variable flip angle pulse sequence according to claim 4 is implemented.

17. A computer-readable storage medium, wherein a computer program is stored in the storage medium, and when the computer program is executed by a processor, the method for optimizing the flip angles in the magnetic resonance variable flip angle pulse sequence according to claim 5 is implemented.

18. A computer electronic device, comprising a memory and a processor;
the memory, configured to store a computer program;
the processor, configured to implement the method for optimizing the flip angles in the magnetic resonance variable flip angle pulse sequence according to claim 2 when executing the computer program.

19. A computer electronic device, comprising a memory and a processor;
the memory, configured to store a computer program;
the processor, configured to implement the method for optimizing the flip angles in the magnetic resonance variable flip angle pulse sequence according to claim 3 when executing the computer program.

20. A computer electronic device, comprising a memory and a processor;
the memory, configured to store a computer program;
the processor, configured to implement the method for optimizing the flip angles in the magnetic resonance variable flip angle pulse sequence according to claim 4 when executing the computer program.
